(19) United States
(12) Patent Application Publication
(10) Pub. No.: US 2010/0021688 A1
(43) Pub. Date: Jan. 28, 2010

(54) WAFER MANUFACTURING METHOD AND WAFER OBTAINED THROUGH THE METHOD

(75) Inventors: Takeo KATOH, Tokyo (JP); Tomohiro HASHII, Tokyo (JP); Katsuhiko MURAYAMA, Tokyo (JP); Sakae KOYATA, Tokyo (JP); Kazushige TAKAISHI, Tokyo (JP)

Correspondence Address: GREENBLUM & BERNSTEIN, P.L.C., 1950 ROLAND CLARKE PLACE, RESTON, VA, 20191, US

(73) Assignee: SUMCO CORPORATION, Tokyo (JP)

(21) Appl. No.: 12/506,290

(22) Filed: Jul. 21, 2009

(30) Foreign Application Priority Data
Jul. 25, 2008 (JP) 2008-192101

(51) Int. Cl. B32B 3/00; H01L 21/306; B24B 7/20; B24B 1/00; H01L 21/322

(52) U.S. Cl. 428/141; 438/692; 451/57; 451/41; 438/476; 257/E21.23; 257/E21.318

(57) ABSTRACT

A wafer manufacturing method includes after flattening both upper and lower surfaces of a wafer sliced from a single crystal ingot, processing the wafer having damage on both surfaces caused by the flattening, so as to obtain desired damage at least on the lower surface of the wafer, the desired damage having a damage depth ranging from 5 nm-10 μm; forming a polysilicon layer at least on the lower surface of the wafer while the damage on the lower surface of the wafer remains; single-wafer etching the upper surface of the wafer; and final polishing the upper surface of the wafer to have a mirrored surface, after the single-wafer etching.

### CROSS-REFERENCE TO RELATED APPLICATIONS

The present application claims priority under 35 U.S.C. §119 of Japanese Application No. 2008-192101, filed on Jul. 25, 2008, the disclosure of which is expressly incorporated by reference herein in its entirety.

### BACKGROUND OF THE INVENTION

1. Field of the Invention

The present invention is related to a wafer manufacturing method and a wafer obtained through the wafer manufacturing method, the wafer having an extrinsic gettering layer on a lower surface.

2. Description of Related Art

For manufacturing semiconductor devices, commonly used is a silicon wafer as a substrate, the silicon wafer being sliced into a predetermined thickness from a silicon single crystal ingot being grown by the Czochralski method (hereinafter referred to as CZ method). For semiconductor devices in recent years, the degree of device integration is extremely high, thus requiring a silicon wafer that is of much higher quality. Therefore, in the device manufacturing process, efforts have been made that include providing a cleaner manufacturing process, and perfecting the surface area of a silicon wafer which is an electrically activated area for a device, i.e., denuding the wafer surface area. In order to denude the surface area of the silicon wafer, it is important to lower the density of a bulk micro defect (hereinafter referred to as BMD) as much as possible, of the surface area of the silicon wafer. A BMD becomes apparent within a silicon wafer by a heating process. When a BMD exists in the surface area of the silicon wafer, it adversely affects reliability and yield of the device.

Further, during the device manufacturing process, there are several manufacturing steps where metal impurities such as Fe, Cu, and Ni may mix in. When such metal impurities exist near the surface area of the wafer, device characteristics become deteriorated and the product yield becomes lowered. Therefore, it is necessary to prevent metal impurities from entering into the surface area of the wafer, which is an electrically active area.

Consequently, technology is deemed important that controls BMD density and removes the contaminating metal impurities from the device forming area (gettering technology). Normally, the gettering technology is classified into an intrinsic gettering method (hereinafter referred to as IG method), an extrinsic gettering method (hereinafter referred to as EG method), and the like.

The IG method produces a denuded zone (hereinafter referred to as DZ zone) with no BMD in the surface area of the wafer by lowering O₂ density in the surface area of the wafer through a high heat treatment, and generates a high density BMD at a location deeper than the DZ zone. In this method, the metal impurities are trapped by the BMD defect. However, the IG method requires a heating process that is complex and for a long period of time in order to create a gettering source. Further, the IG method is not always effective for gettering metal elements having speedy diffusion in silicon, such as Ni.

The EG method includes a method that mechanically adds damage (e.g., sandblasting) and a polysilicon back side method (hereinafter referred to as PBS method) that causes a polysilicon layer to grow on a lower surface of a silicon wafer and utilizes the polysilicon layer as a trap for metal impurities.

The sandblasting method artificially blasts SiO₂ abrasive grains from a jet nozzle on a wafer lower surface through air pressure, mechanically damages the wafer lower surface to create a crystal defect, and utilizes the defect as a trap for metal impurities. However, the method such as sandblasting that adds mechanical damage makes it difficult to completely remove, from the wafer, silicon dust generated during the process of adding mechanical damage, which may cause a new defect. Further, this method also has a difficulty in controlling the lower surface damage, in a quantitative and reproducible manner.

When a silicon wafer is processed in the PBS method and formed with a polysilicon layer on the lower surface (hereinafter referred to as PBS wafer), a heat treatment is performed on the wafer, and metal impurities generated during the device manufacturing process are trapped by the polysilicon layer.

Conventionally, the manufacturing process for a PBS wafer includes, as shown in FIG. 6, slicing of a single crystal ingot pulled up by the CZ method (step 1); and flattening of both surfaces of the sliced wafer (step 2). After the flattening process is performed on the wafer, both the upper and lower surfaces of the wafer are ground one surface at a time (single surface grinding), in order to remove damage caused during the flattening process and to improve precision of the wafer shape (step 3). Then, in order to remove damage caused during the single surface grinding and to mirror-polish the wafer surfaces, both surface simultaneous polishing that polishes both surfaces of the wafer simultaneously is performed (step 4). Next, a polysilicon layer is formed on the lower surface of the wafer (step 5). Further, mirror-polishing is performed only on the upper surface of the wafer (step 6). Furthermore, final polishing is performed only on the upper surface of the wafer (step 7). Accordingly, a desired PBS wafer is produced.

There is another method disclosed in which both surfaces of a wafer sliced from a single crystal ingot are etched after a grinding or lapping process; a polysilicon layer is formed only on the rear surface of the wafer, along the rear surface shape of the wafer after etching in order to obtain the gettering effect; a chemical mechanical polishing is performed on the polysilicon layer; protrusions of the polysilicon layer are removed by flattening; the polysilicon layer is adhered to a carrier plate on a polishing pad; and the front surface of the wafer is mirror-polished (see, e.g., Japanese Patent No. 2839801). According to Japanese Patent No. 2839801, when the degree of flatness of the polysilicon layer formed on the rear surface of the wafer is higher, it is possible to improve the flatness of the mirror-polished front surface of the wafer having the polysilicon layer.

However, the PBS wafer produced from the above-described conventional method has a weak gettering capability, because a polysilicon layer is formed on either an etched surface after etching or on a polished surface after both surface simultaneous polishing.

### SUMMARY OF THE INVENTION

The embodiments of the present invention are provided to address the problems with the conventional technologies above. A non-limiting advantage of the disclosed embodiments of the present invention is to provide a wafer manufacturing method and a wafer obtained through the wafer manufacturing method having an improved extrinsic gettering capability.

One non-limiting aspect of the present embodiments provides a wafer manufacturing method that includes: after flattening both upper and lower surfaces of a wafer sliced from a single crystal ingot, processing the wafer having damage on both surfaces caused by flattening, so as to obtain desired damage at least on the lower surface of the wafer, the desired damage having a damage depth ranging from 5 nm-10 μm; forming a polysilicon layer at least on the lower surface of the wafer while the damage on the lower surface of the wafer remains; single-wafer etching the upper surface of the wafer; and final polishing the upper surface of the wafer to have a mirrored surface, after the single-wafer etching.

In further aspect of the wafer manufacturing method, the processing of the wafer to obtain desired damage is performed by mechanical polishing of both surfaces of the wafer one surface at a time, and a damage depth of damage on at least the lower surface of the wafer is 100-400 nm.

In further aspect of the wafer manufacturing method, the processing of the wafer to have desired damage is performed by mechanical polishing of both surfaces of the wafer one surface at a time and by dry polishing of both surfaces of the wafer one surface at a time, and a damage depth of damage on at least the lower surface of the wafer is 5-20 nm.

In further aspect of the wafer manufacturing method, the polysilicon layer is formed to have a thickness of 0.01-5 μm.

In further aspect of the wafer manufacturing method, stock removal by the single-wafer etching is 2-5 μm.

In another aspect of the present embodiments, a wafer is obtained from the above-described wafer manufacturing method. A lower surface of the wafer has damage having a depth of 5 nm-10 μm; a polysilicon layer is deposited on the lower surface of the wafer having the damage; and an upper surface of the wafer is mirror polished.

According to the wafer manufacturing method of the present invention, it is possible to manufacture a wafer that has an improved EG capability.

### BRIEF DESCRIPTION OF THE DRAWINGS

The present invention is further described in the detailed description which follows, in reference to the noted plurality of drawings by way of non-limiting examples of exemplary embodiments of the present invention, in which like reference numerals represent similar parts throughout the several views of the drawings, and wherein:

FIG. 1 illustrates a manufacturing process of a PBS wafer according to the present invention;

FIG. 2 illustrates a TEM (transmission electron microscope) image from a cross sectional view of a lower surface of a wafer according to a first embodiment of the present invention;

FIG. 3 illustrates a TEM image from a cross sectional view of a lower surface of a wafer according to a second embodiment of the present invention;

FIG. 4 illustrates a TEM image from a cross sectional view of a lower surface of a wafer according to a third embodiment of the present invention;

FIG. 5 illustrates a TEM image from a cross sectional view of a lower surface of a wafer according to a comparative example 1; and

FIG. 6 illustrates a conventional manufacturing process of a PBS wafer.

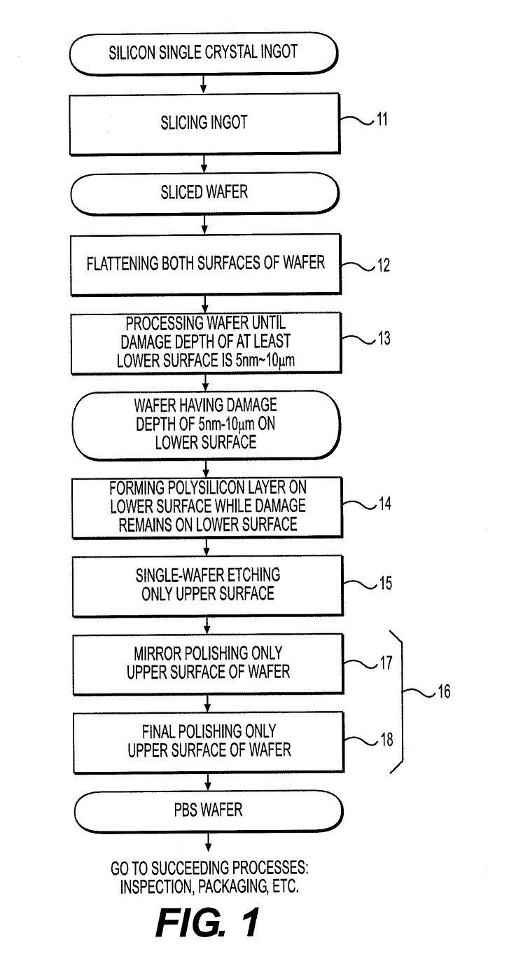

### DETAILED DESCRIPTION OF THE INVENTION

The particulars shown herein are by way of example and for purposes of illustrative discussion of the embodiments of the present invention only and are presented in the cause of providing what is believed to be the most useful and readily understood description of the principles and conceptual aspects of the present invention. In this regard, no attempt is made to show structural details of the present invention in more detail than is necessary for the fundamental understanding of the present invention, the description is taken with the drawings making apparent to those skilled in the art how the forms of the present invention may be embodied in practice.

The preferred embodiments of the present invention are illustrated in the following with reference to the drawings.

A grown silicon single crystal ingot is first subjected to inspections for resistivity and crystallization. Then, both the top and bottom parts of the ingot are cut off, and the ingot is cut into blocks having a predetermined resistivity range. Since the grown ingot as is does not have a perfect cylindrical shape nor has an even diameter, the external periphery of each block is ground to have an even diameter. In order to indicate a specific crystal orientation, orientation flats or orientation notches are given to the blocks having been ground around the external periphery.

After the above-described process, each block is sliced with a predetermined angle in relation to an axial direction (step 11). The sliced wafer is subjected to a bevel grinding on an upper surface periphery portion and a lower surface periphery portion of the wafer, in order to prevent any chipped portion in the periphery of the wafer. By performing the bevel grinding on the upper surface periphery portion and the lower surface periphery portion of the wafer, it is possible to prevent crowning, which has a rising ring shape due to an abnormal growth in the periphery, when there is an epitaxial growth on the silicon wafer surface without beveling, for example.

Next, both surfaces of the wafer are flattened (step 12). This flattening process can be performed by both surface simultaneous grinding that simultaneously grinds both the upper and lower surfaces, or by lapping. The flattening process flattens uneven layers on both surfaces of the wafer created by processes such as slicing, and improves flatness of both surfaces of the wafer and parallelism of the wafer.

Next, the wafer having damage on both surfaces caused by the flattening process is processed so as to obtain desired damage at least on the lower surface of the wafer with a damage depth of 5 nm-10 μm (step 13). The damage depth is set to the above-described range for this step because, when the damage depth is less than the lower threshold, the damage does not work as an EG sink, thereby not contributing to an improvement of the EG capability. When the damage depth exceeds the upper threshold, the damage depth causes cracks and generates dust. A more preferable damage depth for this process is 20 nm-2 μm. Further, this process for obtaining desired damage may be performed by machine polishing both surfaces of the wafer one surface at a time, not only by machine polishing only the lower surface of the wafer. In this case, the damage depth for the damage at least on the lower side is 100-400 nm. The damage depth around 400 nm by machine polishing can be achieved through the use of grinding abrasive stone number #2000. The damage depth around 100 nm by machine polishing can be achieved through the use of grinding abrasive stone number #8000. This process for obtaining desired damage may be performed by first machine polishing both surfaces of the wafer one surface at a time and then dry-polishing both surfaces of the wafer one surface at a time. In this case, the damage depth of at least the lower surface of the wafer is 5-20 nm. The dry-polishing is a method that performs dry process using a polishing cloth in which polishing agent such as silica is embedded, and not using chemicals or slurry. This dry polishing method is also referred to as dry polish. However, it is time consuming and not economical to perform only dry polishing from the damage depth after the flattening process to a desired damage depth. Therefore, it is effective to perform machine polishing up to a predetermined damage depth and then perform dry polishing to obtain a desired damage depth.

Next, a polysilicon layer is formed at least on the lower surface of the wafer while the damage on the lower surface of the wafer remains (step 14). Accordingly, the lower surface of the wafer has both an EG sink attributed to the damage and an EG sink attributed to the polysilicon layer, thereby improving the EG capability compared to a wafer simply having a polysilicon wafer. It is preferable that the polysilicon layer has a thickness ranging from 0.01-5 μm. The thickness is set within the above-described range because when it is less than the lower threshold, there is little gettering effect to be achieved. When the thickness exceeds the upper threshold, the productivity decreases. A more preferable thickness range is 0.8-3 μm. The polysilicon layer can be formed with the conventionally known method and conditions. For example, the polysilicon layer is formed on the lower surface of the silicon wafer by placing a silicon wafer having damage at least on the lower surface in a CVD furnace and by supplying SiH₄ as the raw material in the furnace while heating the silicon wafer to 600-700° C. Alternately, the polysilicon layer may be formed on all surfaces of the wafer, not only the lower surface. In this case, the polysilicon layer formed on the upper surface is removed by a single-wafer etching step that follows.

Next, the upper surface of the wafer is subjected to a single-wafer etching (step 15). This step improves flatness and parallelism of the upper surface of wafer. Further, when a deteriorated layer introduced by mechanical processing remains on the upper surface of the wafer, the single-wafer etching completely removes the deteriorated layer. In addition, when an acid etching liquid is used as the etching liquid, the roughness of the wafer surface can be controlled. The single-wafer etching is an etching method that etches the wafer surfaces one wafer sheet at a time. In this invention, a spin etching technique is employed. The spin etching technique performs the following etching process, for example. First, the wafer is horizontally placed on a supporting table and is spun. While the wafer is spinning, an etching liquid is supplied on the wafer surface from a nozzle. The supplied etching liquid gradually moves from the center of the wafer to an external periphery of the wafer due to a centrifugal force of the spinning wafer, while etching the upper surface of the wafer, and then drips away from the external periphery of the wafer. As to the etching liquid to be used, it is preferable to use aqueous solution containing each of hydrofluoric acid, nitric acid, and phosphoric acid. Further, it is preferable to prepare the aqueous solution having a mixture rate in mass % of hydrofluoric acid:nitric acid:phosphoric acid=0.5-40%:5-50%:5-70%. The stock removal by the single-wafer etching is set at 2-5 μm. The stock removal is set to the above-described range because when the stock removal is set below the lower threshold, the etching is not performed evenly, and makes it impossible to remove a polysilicon layer or damage when they are formed on the upper surface. Further, when the stock removal exceeds the upper threshold, the shape of the wafer is altered more than necessary.

Instead of the both surface simultaneous polishing employed conventionally, it is possible to perform a single surface polishing only on the upper side without using the single-wafer etching employed in the present invention. However, this method is not preferable since the wafer is scratched during the single surface polishing.

After the single-wafer etching, it is preferable that the wafer surface is supplied with deionized water for rinsing, while being spun, and then sprayed with the nitrogen and dried.

Further, the upper surface of the wafer after the single-wafer etching is subjected to a final polishing for mirror polishing (step 16). When it is impossible to decrease the roughness of the upper surface with a normally performed final polishing, this process can be performed a plurality of times (steps 17 & 18).

A desired PBS wafer is manufactured according to the above-described procedure.

The wafer according to the present invention is obtained from the above-described method and has a damage depth of 5 nm-10 μm on the lower surface of the wafer. A polysilicon layer is deposited on the lower surface having the damage, and the upper surface of the wafer is subjected to a mirror-polish process.

Accordingly, the lower surface of the wafer has both an EG sink attributed to the damage and an EG sink attributed to the polysilicon layer, thereby improving the EG capability compared to a wafer simply having a polysilicon wafer on the lower surface.

The embodiments of the present invention are hereafter illustrated as follows, together with comparative examples.

### First Embodiment

First, a silicon single crystal ingot was prepared in order to manufacture a wafer having a diameter of 300 mm, and a plurality of sliced wafers were obtained from the ingot. Next, the periphery of the sliced wafer was subjected to a beveling process. Then, as a flattening process, both surface grinding that simultaneously grinds both the upper and lower surfaces of the wafer was performed by using a grinding apparatus (not shown).

Succeedingly, single surface grinding was performed only on the upper surface of the wafer, by using a single surface grinding apparatus (not shown), after the wafer was subjected to the flatting process, with use of a grinding stone having abrasive number #2000. Then, with a similar condition, only the lower surface of the wafer was subjected to a single surface grinding. Thereby, both surfaces of the wafer were given damage through this process.

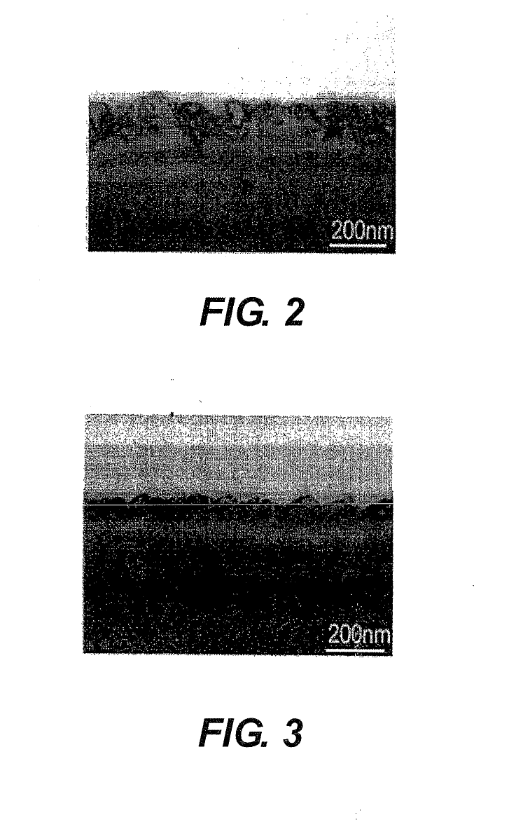

After the single surface grinding through the use of #2000 grinding stone, a cross section of the wafer lower surface was measured with a transmission electron microscope (TEM) to evaluate a damage depth of the cross section of the lower surface. The damage depth was measured at 400 nm. FIG. 2 shows a TEM image measured herein.

Then, on the wafer with damage remaining on both the upper and lower surfaces, a polysilicon layer of 0.8 μm thickness was formed on the entire surfaces of the wafer through the CVD method. SiH₄ was used as the raw material and the temperature for the layer deposit was set at 650° C.

Next, single-wafer etching was performed on the upper surface of the wafer by using a single-wafer etching apparatus, in order to remove the polysilicon layer and damage formed on the upper surface. An acid etching liquid was used as the etching liquid, the liquid having a mixture rate in mass % of hydrofluoric acid:nitric acid:phosphoric acid:water=10%:30%:30%:30%. The wafer spinning speed for the etching was set at 600 rpm, and the etching liquid amount to be provided was set at 3 liter/minute. The etching was performed for 10 seconds. The stock removal by this single-wafer etching was 2 μm.

After etching, wafer surface was supplied with deionized water for rinsing, while the wafer was spun. The wafer surface was sprayed with nitrogen and dried.

Further, final polishing was performed to mirror polish the upper surface of the wafer after the single-wafer etching was completed. Accordingly, a PBS wafer was obtained. The stock removal by this final polishing was set at 0.1 μm.

### Second Embodiment

After the wafer was flattened, a PBS wafer was obtained in a similar manner to the first embodiment, except that the single surface grinding was performed by using a grinding stone having abrasive number #8000, instead of the single surface grinding using the grinding stone having abrasive number #2000.

After the single surface grinding through the use of #8000 grinding stone, a cross section of the wafer lower surface was measured with a TEM to evaluate the damage depth of the cross section of the lower surface. The damage depth was measured at 100 nm. FIG. 3 shows a TEM image measured herein.

### Third Embodiment

After the wafer was flattened, a PBS wafer was obtained in a similar manner to the first embodiment, except that the single surface grinding was performed by using a grinding stone having abrasive number #2000 and dry polishing was further performed, instead of just the single surface grinding using the grinding stone having abrasive number #2000.

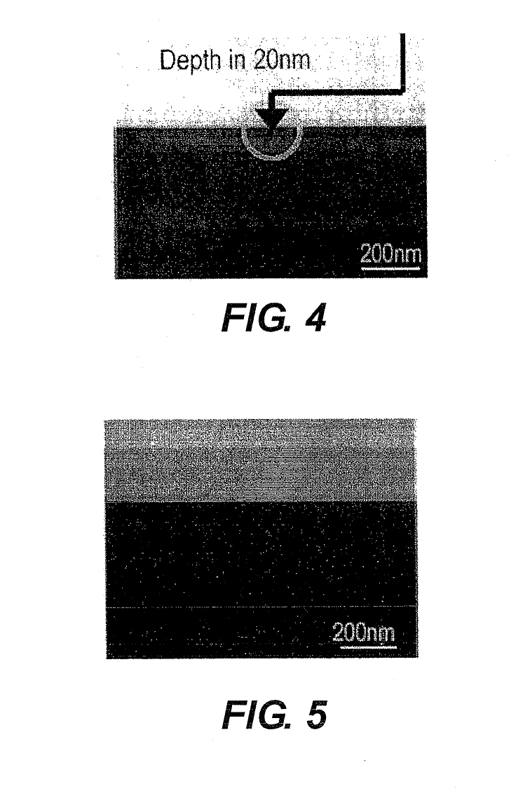

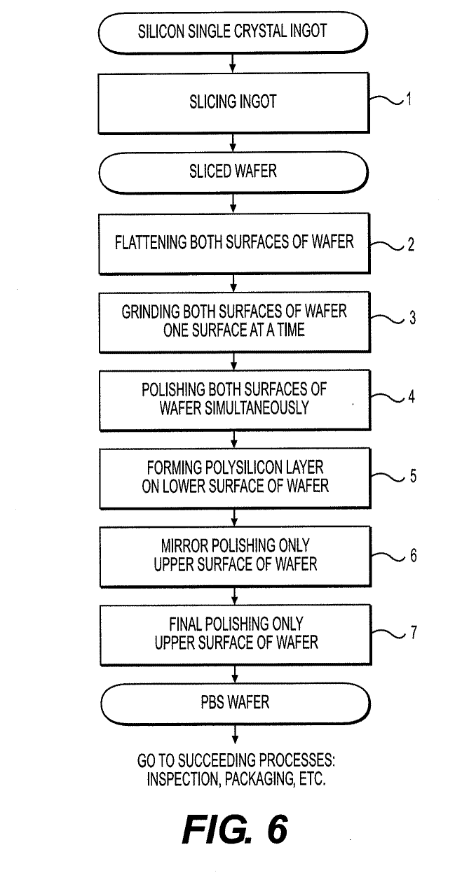

After the dry polishing was performed, a cross section of the wafer lower surface was measured with a TEM to evaluate the damage depth of the cross section of the lower surface. The damage depth was measured at 20 nm. FIG. 4 shows a TEM image measured herein.

### Comparative Example 1

After the wafer was flattened, a PBS wafer was obtained in a similar manner to the first embodiment, except that both surface simultaneous polishing was performed that simultaneously polishes both the upper and lower surfaces of the wafer, instead of the single surface grinding using the grinding stone having abrasive number #2000.

After the both surface simultaneous polishing was performed, a cross section of the wafer lower surface was measured with a TEM to evaluate the damage depth of the cross section of the lower surface. The damage was not found, therefore the damage depth was evaluated as 0 nm. FIG. 5 shows a TEM image measured herein.

### Comparative Test 1

The EG capability of the PBS wafers obtained from the first through third embodiments and comparative example 1 were evaluated, using the following method. First, a solution containing Ni having concentration of 1×10¹² atoms/cm³ was dropped on the upper surface of the wafer. The wafer was spin-coated and the upper surface of the wafer was forcibly contaminated. Then, the forcibly contaminated wafer was diffusion-heat treated that retained the wafer at a 900° C. nitrogen atmosphere for 30 minutes. Further, the Ni residual amount was measured on the upper surface of the wafer by the atomic absorption method. The measurement results are individually shown in Chart 1.

### Comparative Test 2

Further, the EG capability of the PBS wafers obtained from the first through third embodiments and comparative example 1 were evaluated by measuring the metal residual amount on the upper surface of the wafer in the similar method to the above comparative test 1, except that the metal element for forcible contamination was changed from Ni to Cu. The measurement results are individually shown in Chart 1.

CHART 1

| | | | Metal residual amount | |
|---|---|---|---|---|
| | | Damage depth | on upper surface | |
| | Lower surface damage processing | of lower | [/cm²] | |
| | prior to forming polysilicon layer | surface [nm] | Ni | Cu |
| Embodiment 1 | Single surface grinding (grinding | 400 | 3.4 × 10⁸ | 4.2 × 10⁸ |
| | abrasive stone No. #2000) | | | |
| Embodiment 2 | Single surface grinding (grinding | 100 | 7.3 × 10⁸ | 6.5 × 10⁸ |
| | abrasive stone No. #8000) | | | |
| Embodiment 3 | Single surface grinding (grinding | 20 | 2.6 × 10⁹ | 8.7 × 10⁹ |
| | abrasive stone No. #2000) + dry | | | |
| | polishing | | | |
| Comparative | Both surface simultaneous polishing | 0 | 5.7 × 10¹⁰ | 4.2 × 10¹⁰ |
| Example 1 | | | | |

As it is apparent from Chart 1, by comparing the first through third embodiments and comparative example 1, comparative example 1 has an order of 10¹⁰/cm². In contrast, the first through third embodiments have 10⁸-10⁹/cm² orders. Therefore, large differences in EG capabilities were seen. It is considered that it is because the wafer in comparative example 1 subjected to the both surface simultaneous polishing prior to forming the polysilicon layer did not have any damage under the polysilicon layer, and only the polysilicon layer has become the EG sink. Therefore, there is a high level of metal residual amount.

Further, in the third embodiment where the dry polishing was performed following the machine polishing, the damage depth is smaller than the first and second embodiments. Therefore, the result of the third embodiment is inferior to the first and second embodiments, yet having a superior result to comparative example 1 that has substantially no damage depth.

Accordingly, it is confirmed with the method according to the present invention, that the EG capability is improved by combining mechanical damage and a polysilicon layer.

It is noted that the foregoing examples have been provided merely for the purpose of explanation and are in no way to be construed as limiting of the present invention. While the present invention has been described with reference to exemplary embodiments, it is understood that the words which have been used herein are words of description and illustration, rather than words of limitation. Changes may be made, within the purview of the appended claims, as presently stated and as amended, without departing from the scope and spirit of the present invention in its aspects. Although the present invention has been described herein with reference to particular structures, materials and embodiments, the present invention is not intended to be limited to the particulars disclosed herein; rather, the present invention extends to all functionally equivalent structures, methods and uses, such as are within the scope of the appended claims.

The present invention is not limited to the above described embodiments, and various variations and modifications may be possible without departing from the scope of the present invention.

What is claimed is:

1. A wafer manufacturing method comprising:
flattening both upper and lower surfaces of a wafer sliced from a single crystal ingot,
processing the wafer having damage on both surfaces caused by said flattening so as to obtain desired damage at least on the lower surface of the wafer, the desired damage having a damage depth ranging from 5 nm-10 μm;
forming a polysilicon layer at least on the lower surface of the wafer while the damage on the lower surface of the wafer remains;
single-wafer etching the upper surface of the wafer; and
polishing the upper surface of the wafer to have a mirrored surface, after said single-wafer etching.

2. The wafer manufacturing method according to claim 1, wherein said processing the wafer is performed by mechanical polishing of both surfaces of the wafer one surface at a time, and a damage depth of damage on at least the lower surface of the wafer is 100-400 nm.

3. The wafer manufacturing method according to claim 1, wherein said processing the wafer is performed by mechanical polishing of both surfaces of the wafer one surface at a time and by dry polishing of both surfaces of the wafer one surface at a time, and a damage depth of damage on the at least the lower surface of the wafer is 5-20 nm.

4. The wafer manufacturing method according to claim 1, wherein the polysilicon layer is formed to have a thickness of 0.01-5 μm.

5. The wafer manufacturing method according to claim 1, wherein stock removal by the single-wafer etching is 2-5 μm.

6. A wafer obtained from the wafer manufacturing method according to claim 1, wherein:
a lower surface of the wafer has damage having a depth of 5 nm-10 μm;
a polysilicon layer is deposited on the lower surface of the wafer having the damage; and
an upper surface of the wafer is mirror polished.

7. A wafer obtained from the wafer manufacturing method according to claim 2, wherein:
a lower surface of the wafer has damage having a depth of 5 nm-10 μm;
a polysilicon layer is deposited on the lower surface of the wafer having the damage; and
an upper surface of the wafer is mirror polished.

8. A wafer obtained from the wafer manufacturing method according to claim 3, wherein:
a lower surface of the wafer has damage having a depth of 5 nm-10 μm;
a polysilicon layer is deposited on the lower surface of the wafer having the damage; and
an upper surface of the wafer is mirror polished.

9. A wafer obtained from the wafer manufacturing method according to claim 4, wherein:
a lower surface of the wafer has damage having a depth of 5 nm-10 μm;
a polysilicon layer is deposited on the lower surface of the wafer having the damage; and
an upper surface of the wafer is mirror polished.

10. A wafer obtained from the wafer manufacturing method according to claim 5, wherein:
a lower surface of the wafer has damage having a depth of 5 nm-10 μm;
a polysilicon layer is deposited on the lower surface of the wafer having the damage; and
an upper surface of the wafer is mirror polished.
